(19) United States
(12) Patent Application Publication
(10) Pub. No.: US 2019/0287898 A1
(43) Pub. Date: Sep. 19, 2019

(54) METHODS AND APPARATUS FOR EMBEDDED ANTIFUSES

(71) Applicant: APPLIED MATERIALS, INC., Santa Clara, CA (US)

(72) Inventors: PENG SUO, SINGAPORE (SG); YU GU, SINGAPORE (SG); GUAN HUEI SEE, SINGAPORE (SG); ARVIND SUNDARRAJAN, SINGAPORE (SG)

(21) Appl. No.: 16/296,929

(22) Filed: Mar. 8, 2019

Related U.S. Application Data
(60) Provisional application No. 62/643,915, filed on Mar. 16, 2018.

(51) Int. Cl. H01L 23/525

(52) U.S. Cl. CPC H01L 23/5252

(57) ABSTRACT

Methods and apparatus for forming an embedded antifuse in a wafer-level packaging compatible process. In some embodiments, a method for forming an embedded antifuse includes forming a first redistribution layer on a first polymer layer, depositing an antifuse dielectric layer on the first redistribution layer, forming a second polymer layer on the antifuse dielectric layer, creating at least one first via through the second polymer layer to the antifuse dielectric layer using a lithography process with, for example, a dielectric etch, and forming a second redistribution layer on the second polymer layer and contacting the antifuse dielectric layer at a bottom of the at least one first via.

### CROSS-REFERENCE TO RELATED APPLICATIONS

This application claims benefit of U.S. provisional patent application Ser. No. 62/643,915, filed Mar. 16, 2018 which is herein incorporated by reference in its entirety.

### FIELD

Embodiments of the present principles generally relate to semiconductor processes.

### BACKGROUND

Antifuses are electrically programmable devices which are normally in a high resistance state when constructed and can be programmed to a low resistance state by applying a high voltage or forcing a high current through the device. Antifuses are widely used in integrated circuits (IC) design for circuit trimming and/or field programmable applications. Conventional antifuses are typically constructed on back end of line (BEOL) processes or use discrete resistors or wire bonds in semiconductor packaging. Conventional BEOL antifuses occupy valuable real estate on a silicon chip, making the chip bigger with a lower yield and a higher cost. Discrete resistor or wire bond antifuses require flip-chip or wire bond processes and are not compatible with standard wafer level packaging flows.

Thus, the inventors have provided improved methods and apparatus for embedding antifuses in wafer level packaging processes.

### SUMMARY

Methods and apparatus provide embedded antifuse devices used in wafer level packaging of semiconductor processes.

In some embodiments, a method of constructing an embedded antifuse in a wafer-level packaging compatible process comprising forming a first redistribution layer on a first polymer layer, depositing an antifuse dielectric layer on the first redistribution layer, forming a second polymer layer on the antifuse dielectric layer, creating at least one via through the second polymer layer to the antifuse dielectric layer using a lithography process, and forming a second redistribution layer on the second polymer layer and contacting the antifuse dielectric layer at a bottom of the at least one via.

In some embodiments, the method can further comprise removing a portion of the antifuse dielectric layer after deposition from a surface of the first polymer layer and the first redistribution layer; forming at least one of the first redistribution layer or the second redistribution layer using a semi-additive process (SAP); a fan-in or fan-out wafer-level packaging compatible process; depositing an antifuse dielectric layer comprising a material based on at least one of amorphous silicon, silicon nitride, silicon oxide, silicon carbide, or metal oxide; and/or forming at least one of the first polymer layer or the second polymer layer from a material based on at least one of polybenzoxazole (PBO), polyimide, benzocyclobutene (BCB), epoxy, or photo-sensitive material.

In some embodiments, a method of constructing an embedded antifuse in a wafer-level packaging compatible process comprises forming a first redistribution layer on a first polymer layer, forming a second polymer layer on the first redistribution layer, creating at least one via through the second polymer layer to the first redistribution layer using a lithography process, depositing an antifuse dielectric layer on the second polymer layer and in the at least one via, contacting the first redistribution layer at a bottom of the at least one via, and forming a second redistribution layer on the second polymer layer and the antifuse dielectric layer.

In some embodiments, the method can further comprise removing a portion of the antifuse dielectric layer after deposition from a surface of the second polymer layer; forming at least one of the first redistribution layer or the second redistribution layer using a semi-additive process (SAP); a fan-in or fan-out wafer-level packaging compatible process; depositing an antifuse dielectric layer comprising a material based on at least one of amorphous silicon, silicon nitride, silicon oxide, silicon carbide, or metal oxide; and/or forming at least one of the first polymer layer or the second polymer layer from a material based on at least one of polybenzoxazole (PBO), polyimide, benzocyclobutene (BCB), epoxy, or photo-sensitive material.

In some embodiments, a method of constructing an embedded antifuse in a wafer-level packaging compatible process comprises forming a first redistribution layer on a first polymer layer, forming a plurality of second polymer layers on the first redistribution layer, creating at least one via through the plurality of second polymer layers to the first redistribution layer using a lithography and dry etch process, depositing an antifuse dielectric layer on an uppermost surface of the plurality of second polymer layers and in the at least one via, the antifuse dielectric layer contacting the first redistribution layer at a bottom of the at least one via, and forming a second redistribution layer on the plurality of second polymer layers, the second redistribution layer contacting the antifuse dielectric layer at least on a side of the at least one via and at the bottom of the at least one via.

In some embodiments, the method can further comprise removing a portion of the antifuse dielectric layer after deposition from the uppermost surface of the plurality of second polymer layers; forming at least one of the first redistribution layer or the second redistribution layer using a semi-additive process (SAP); a fan-in or fan-out wafer-level packaging compatible process; depositing an antifuse dielectric layer comprising a material based on at least one of amorphous silicon, silicon nitride, silicon oxide, silicon carbide, or metal oxide; forming at least one of the first polymer layer or at least one of the plurality of second polymer layers from a material based on at least one of polybenzoxazole (PBO), polyimide, benzocyclobutene (BCB), epoxy, or photo-sensitive material; and/or etching a portion of the antifuse dielectric layer after deposition from the uppermost surface of the plurality of second polymer layers.

In some embodiments, an apparatus for an embedded antifuse comprises a first redistribution layer formed on a first polymer layer, a plurality of second polymer layers formed on the first redistribution layer and the first polymer layer, at least one via extending from a top surface of one of the plurality of second polymer layers to the first redistribution layer, an antifuse dielectric layer formed in the at least one via and on the first redistribution layer at a bottom of the at least one via, and a second redistribution layer formed at least on the antifuse dielectric layer in at least the at least one via.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of forming an antifuse in accordance with some embodiments of the present principles.

FIGS. 2A-2E are schematic views of an antifuse formed according to the method of FIG. 1 in accordance with some embodiments of the present principles.

FIG. 3 is a method of forming an antifuse in accordance with some embodiments of the present principles.

FIGS. 4A-4E are schematic views of an antifuse formed according to the method of FIG. 3 in accordance with some embodiments of the present principles.

FIG. 5 is a method of forming an antifuse in accordance with some embodiments of the present principles.

FIGS. 6A-6E are schematic views of an antifuse formed according to the method of FIG. 5 in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Two-dimensional (2D) and three-dimensional (3D) antifuse structures are created using an integration process to form the antifuses. The processes can be incorporated into a generic wafer level packaging flow, either fan-in or fan-out. The antifuses can be used in, for example, one-time programmable devices for precision circuit trimming and/or circuit matching or for dynamic random access memory (DRAM) repair circuitry and the like. The antifuses, using the present principles, advantageously save valuable real estate on semiconductor chips, lower costs, and provide better yields. The antifuses of the present principles, advantageously, do not require flip-chips or wire bond processes which are incompatible with wafer level packaging processes and are not electrically programmable after fabrication. The antifuses of the present principles are programmable after fabrication, beneficially allowing greater design and manufacturing flexibility and are compatible with wafer level packaging processes, advantageously reducing chip packaging sizes and costs.

In some embodiments, an embedded antifuse is constructed as a 2D structure with an antifuse dielectric on top of a metal layer (redistribution layer). In some embodiments, an embedded antifuse is constructed as a 3D structure with an antifuse dielectric inside a polymer via in a polymer layer formed by a lithography and dry etch process. In some embodiments, an embedded antifuse is constructed as a 3D structure with an antifuse dielectric inside a high aspect ratio polymer via through multiple polymer layers formed by a lithography method. In some embodiments, methods are used to embed an antifuse device in a wafer-level packaging redistribution layers, advantageously allowing programming of antifuse devices after fabrication and increasing flexibility in terms of management and design without using additional wire bonding or additional passive devices to attach to a semiconductor package.

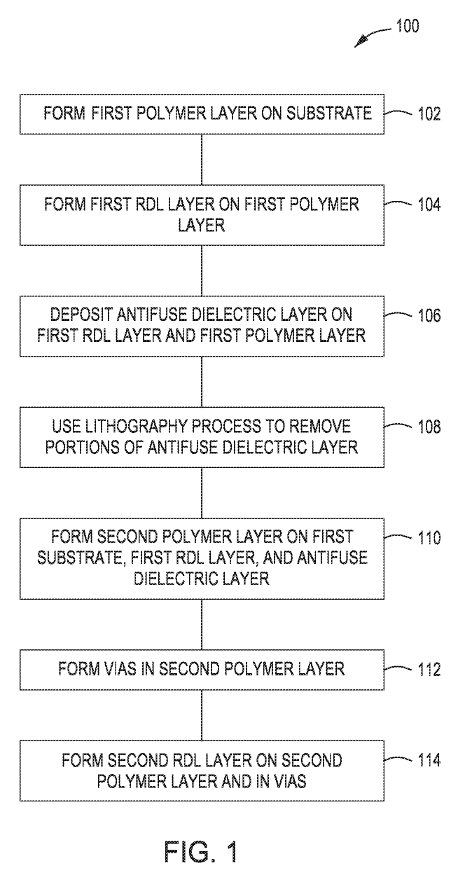

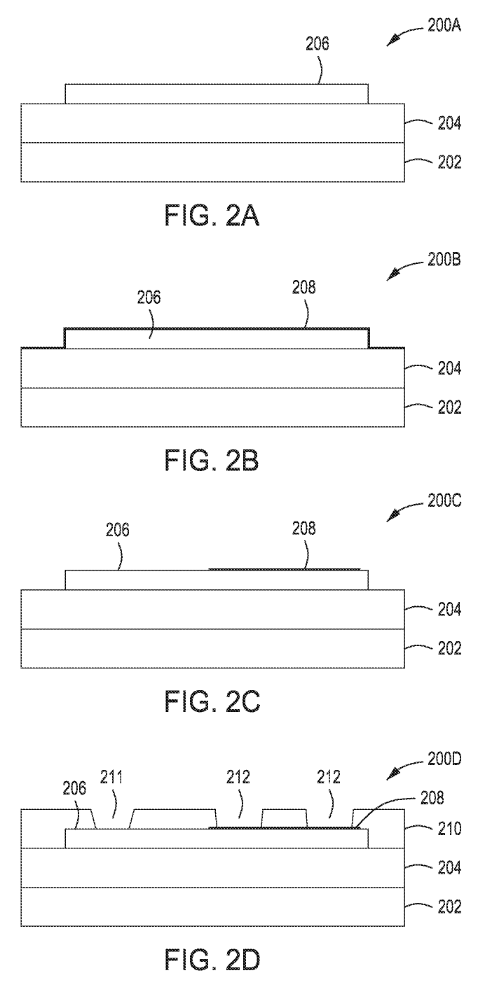

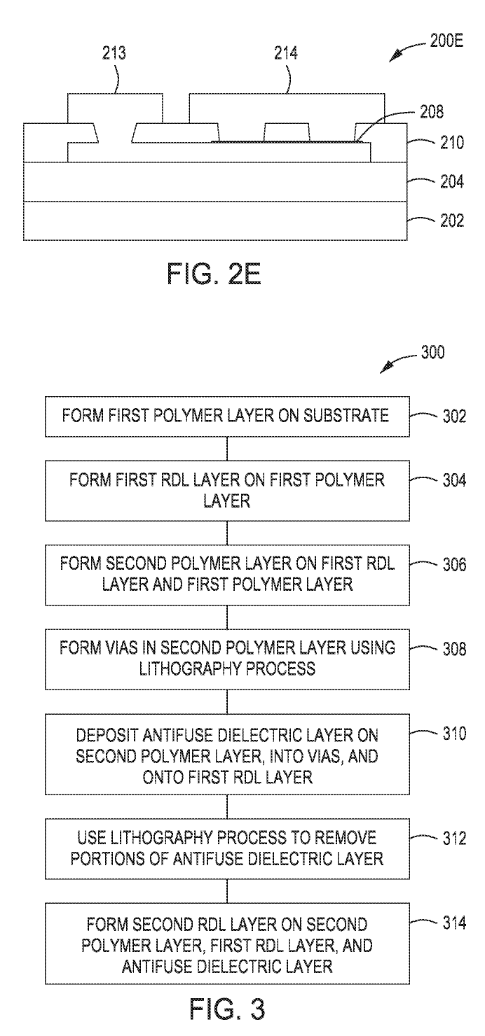

FIG. 1 is a method 100 of forming an antifuse in accordance with some embodiments. FIGS. 2A-2E are schematic views of an antifuse formed, for example, according to the method 100 of FIG. 1 in accordance with some embodiments and will be referenced with the description of method 100. The method 100 is compatible with wafer-level packaging processes. In block 102 of the method 100, a first polymer layer 204 is formed on a substrate 202 as shown in a view 200A of FIG. 2A. The first polymer layer 204 may be deposited using any suitable spin-coating process or lithographic process. In some embodiments, the first polymer layer 204 is a polybenzoxazole (PBO) layer, a polyimide layer, a benzocyclobutene (BCB) layer, an epoxy layer, or a photo-sensitive material layer. In block 104 of the method 100, a first redistribution layer (RDL) 206 is formed on the first polymer layer 204. In some embodiments, the first RDL layer 206 may be formed using a semi-additive process (SAP). In block 106 of the method 100, an antifuse dielectric layer 208 is deposited on the first RDL layer 206 and the first polymer layer 204 as shown in a view 200B of FIG. 2B. The antifuse dielectric layer 208 may comprise a material based on, for example, amorphous silicon, silicon nitride, silicon oxide, silicon carbide, and/or metal oxide and the like.

In block 108 of the method 100, a lithography process is used to delineate an area of the antifuse dielectric layer 208 to remain after using, for example, a dielectric etch method to remove portions of the antifuse dielectric layer 208 from the first polymer layer 204 and the first RDL layer 206. A view 200C of FIG. 2C illustrates an example of the antifuse dielectric layer 208 after the dry etch method is completed. In block 110 of method 100, a second polymer layer 210 is formed over the first polymer layer 204, the first RDL layer 206, and the antifuse dielectric layer 208 as depicted, for example, in a view 200D of FIG. 2D. The second polymer layer 210 may be deposited using any suitable spin-coating process or lithographic process. In some embodiments, the second polymer layer 210 is a polybenzoxazole (PBO) layer, a polyimide layer, a benzocyclobutene (BCB) layer, an epoxy layer, or a photo-sensitive material layer. In block 112 of method 100, vias 211, 212 are formed, for example, into the second polymer layer 210. The vias 211, 212 form openings in the second polymer layer to, for example, the first RDL layer 206 (via 211) and/or the antifuse dielectric layer 208 (vias 212). In block 114 of the method 100, a second RDL layer 213, 214 is formed on the second polymer layer and in the vias 211, 212 as shown in a view 200E of FIG. 2E. In some embodiments, the second RDL layer 213, 214 may be formed using a semi-additive process (SAP). In the foregoing example of some embodiments, a 2D antifuse is created by the first RDL layer 206, the antifuse dielectric layer 208, and the second RDL layer 214. A voltage applied to the first RDL layer 206 and the second RDL layer 214 or a current applied through the antifuse dielectric layer 208 may be used to program the antifuse from a high resistive state to a low resistive state.

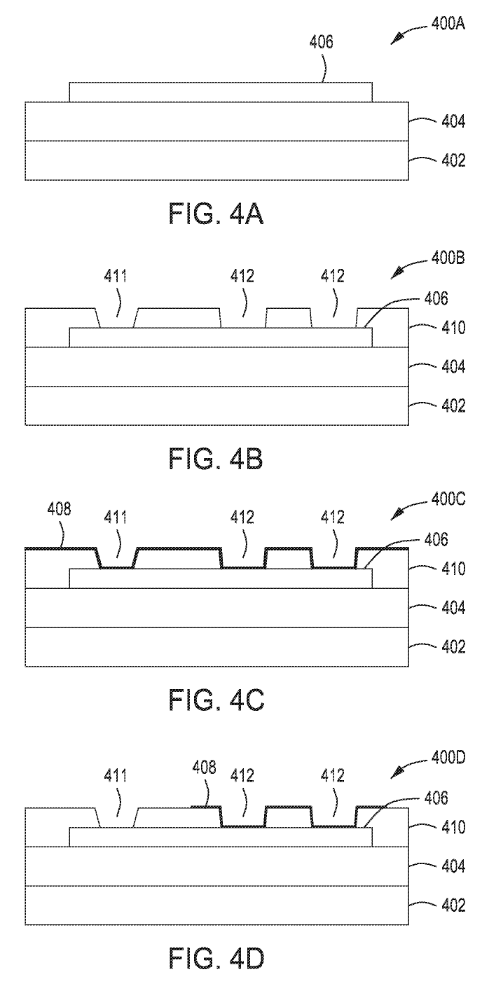

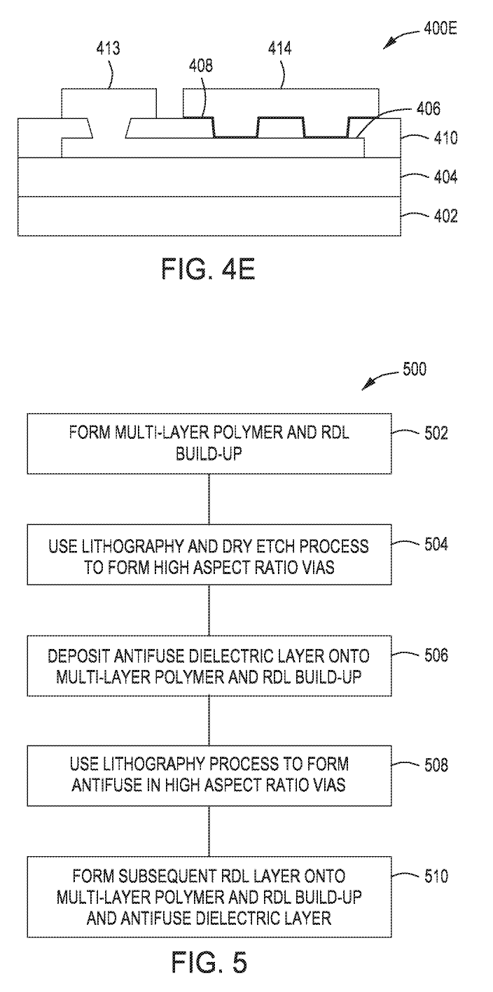

FIG. 3 is a method 300 of forming a 3D antifuse in accordance with some embodiments. FIGS. 4A-4E are schematic views of an antifuse formed, for example, according to the method 300 of FIG. 3 in accordance with some embodiments and will be referenced with the description of method 300. The method 300 is compatible with wafer-level packaging processes. In block 302 of the method 300, a first polymer layer 404 is formed on a substrate 402 as shown, for example, in a view 400A of FIG. 4A. The first polymer layer 404 may be deposited using any suitable spin-coating process or lithographic process. In some embodiments, the first polymer layer 404 is a polybenzoxazole (PBO) layer, a polyimide layer, a benzocyclobutene (BCB) layer, an epoxy layer, or a photo-sensitive material layer. In block 304 of the method 300, a first RDL layer 406 is formed on the first polymer layer 404. In some embodiments, the first RDL layer 406 may be formed using a semi-additive process (SAP). In block 306 of the method 300, a second polymer layer 410 is formed on the first RDL layer 406 and the first polymer layer 404 as depicted, for example, in a view 400B of FIG. 4B. In some embodiments, the second polymer layer 410 is a polybenzoxazole (PBO) layer, a polyimide layer, a benzocyclobutene (BCB) layer, an epoxy layer, or a photo-sensitive material layer. In block 308 of the method 300, vias 411, 412 are formed in the second polymer layer 410 to create openings to the first RDL layer 406.

In block 310 of the method 300, an antifuse dielectric layer 408 is deposited on the second polymer layer 410, into the vias 411, 412, and onto the first RDL layer 406 as illustrated, for example, in a view 400C of FIG. 4C. The antifuse dielectric layer 408 may comprise material based on, for example, amorphous silicon, silicon nitride, silicon oxide, silicon carbide, and/or metal oxide and the like. In block 312 of the method 300, a lithography process with, for example, a dry etch process are used to remove portions of the antifuse dielectric layer 408 as shown, for example, in a view 400D of FIG. 4D. In some embodiments, the remaining portions of the antifuse dielectric layer 408 line the vias 412 and are in direct contact with the first RDL layer 406 at the bottom of the vias 412. In block 314 of the method 300, a second RDL layer 413, 414 is formed on the second polymer layer 410, the first RDL layer 406, and the antifuse dielectric layer 408 as depicted, for example, in a view 400E of FIG. 4E. In some embodiments, the second RDL layer 413, 414 may be formed using a semi-additive process (SAP). In the foregoing example of some embodiments, a 3D antifuse is created by the first RDL layer 406, the antifuse dielectric layer 408, and the second RDL layer 414. A voltage applied to the first RDL layer 406 and the second RDL layer 414 or a current applied through the antifuse dielectric layer 408 may be used to program the antifuse from a high resistive state to a low resistive state.

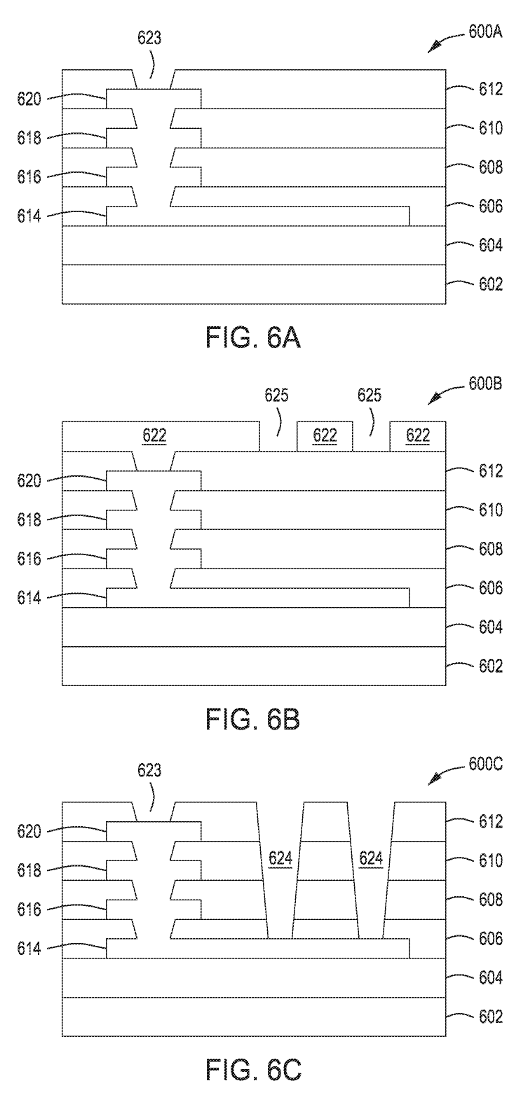

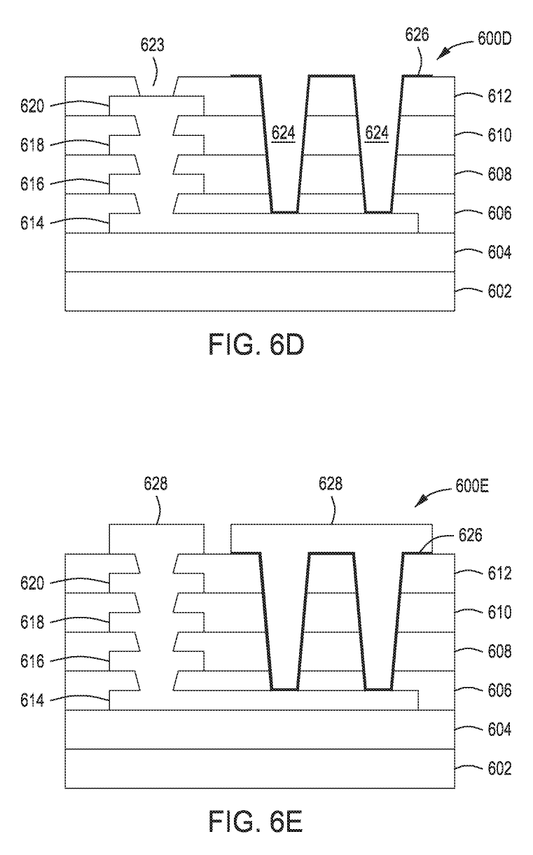

FIG. 5 is a method 500 of forming a high aspect ratio, 3D antifuse in accordance with some embodiments. FIGS. 6A-6E are schematic views of an antifuse formed, for example, according to the method 500 of FIG. 5 in accordance with some embodiments and will be referenced with the description of method 500. The method 500 is compatible with wafer-level packaging processes. In block 502 of the method 500, multiple polymer layers 604-612 and multiple RDL layers 614-620 are formed on a substrate 602 as shown, for example, in a view 600A of FIG. 6A. In some embodiments, the multiple polymer layers 604-612 are polybenzoxazole (PBO) layers, polyimide layers, benzocyclobutene (BCB) layers, epoxy layers, photo-sensitive material layers, or a combination of different types of layers. In some embodiments, one or more of the multiple RDL layers 614-620 may be formed using a semi-additive process (SAP). A via 623 has been formed using lithography processes to expose a top RDL layer 620. In block 504 of the method 500, a high aspect ratio lithography process is used to mask areas 622 of an uppermost polymer layer 612 to create open areas 625 for the etching of two or more of the polymer layers 606-612 as shown, for example, in a view 600B of FIG. 6B. A view 600C of FIG. 6C, for example, illustrates vias 624 formed through the plurality of polymer layers 606-612 to a lowermost RDL layer 614 using, for example, a dry etch process.

In block 506 of method 500, an antifuse dielectric layer 626 is deposited onto the polymer layers 606-612 and the top RDL layer 620 a shown, for example, in a view 600D of FIG. 6D. The antifuse dielectric layer 626 may comprise material based on, for example, amorphous silicon, silicon nitride, silicon oxide, silicon carbide, and/or metal oxide and the like. In some embodiments, the antifuse dielectric layer 626 extends into vias 624 (through a plurality of polymer layers 606-612) and is in direct contact with the lowermost RDL layer 614. A lithography and etching process removes other portions of the antifuse dielectric layer 626 on portions of the uppermost polymer layer 612 and from the top RDL layer 620 in the via 623. In block 510 of the method 500, a subsequent RDL layer 628 is formed on the uppermost polymer layer 612 and the top RDL layer 620 in the via 623 as depicted, for example, in a view 600E of FIG. 6E. In the foregoing example of some embodiments, a high aspect ratio, 3D antifuse is created through a plurality of polymer layers 606-612 by the lowermost RDL layer 614, the antifuse dielectric layer 626, and the subsequent RDL layer 628. A voltage applied to the subsequent RDL layer 628 and the lowermost RDL layer 614 or a current applied through the antifuse dielectric layer 626 may be used to program the antifuse from a high resistive state to a low resistive state.

The methods and apparatus of the present principles allow for the 2D and/or 3D antifuses to be part of a wafer-level process at any stage. The antifuses may be incorporated into any layer of a process such that the antifuses may be embedded under any number of layers and/or interconnected to any number of semiconductor devices, advantageously allowing for greater flexibility in package design and cost savings.

While the foregoing is directed to embodiments of the present principles, other and further embodiments of the principles may be devised without departing from the basic scope thereof.

1. A method of constructing an embedded antifuse in a wafer-level packaging compatible process, comprising:
forming a first redistribution layer on a first polymer layer;
depositing an antifuse dielectric layer on the first redistribution layer;
forming a second polymer layer on the antifuse dielectric layer;
creating at least one via through the second polymer layer to the antifuse dielectric layer using a lithography process; and
forming a second redistribution layer on the second polymer layer and contacting the antifuse dielectric layer at a bottom of the at least one via.

2. The method of claim 1, further comprising:
removing a portion of the antifuse dielectric layer after deposition from a surface of the first polymer layer and the first redistribution layer.

3. The method of claim 1, further comprising:
forming at least one of the first redistribution layer or the second redistribution layer using a semi-additive process (SAP).

4. The method of claim 1 comprising a fan-in or fan-out wafer-level packaging compatible process.

5. The method of claim 1, further comprising:
depositing an antifuse dielectric layer comprising a material based on at least one of amorphous silicon, silicon nitride, silicon oxide, silicon carbide, or metal oxide.

6. The method of claim 1, further comprising:
forming at least one of the first polymer layer or the second polymer layer from a material based on at least one of polybenzoxazole (PBO), polyimide, benzocyclobutene (BCB), epoxy, or photo-sensitive material.

7. A method of constructing an embedded antifuse in a wafer-level packaging compatible process, comprising:
forming a first redistribution layer on a first polymer layer;
forming a second polymer layer on the first redistribution layer;
creating at least one via through the second polymer layer to the first redistribution layer using a lithography process;
depositing an antifuse dielectric layer on the second polymer layer and in the at least one via, contacting the first redistribution layer at a bottom of the at least one via; and
forming a second redistribution layer on the second polymer layer and the antifuse dielectric layer.

8. The method of claim 7, further comprising:
removing a portion of the antifuse dielectric layer after deposition from a surface of the second polymer layer.

9. The method of claim 7, further comprising:
forming at least one of the first redistribution layer or the second redistribution layer using a semi-additive process (SAP).

10. The method of claim 7 comprising a fan-in or fan-out wafer-level packaging compatible process.

11. The method of claim 7, further comprising:
depositing an antifuse dielectric layer comprising a material based on at least one of amorphous silicon, silicon nitride, silicon oxide, silicon carbide, or metal oxide.

12. The method of claim 7, further comprising:
forming at least one of the first polymer layer or the second polymer layer from a material based on at least one of polybenzoxazole (PBO), polyimide, benzocyclobutene (BCB), epoxy, or photo-sensitive material.

13. The method of claim 7, further comprising:
forming a plurality of second polymer layers on the first redistribution layer;
creating the at least one via through the plurality of second polymer layers to the first redistribution layer using a lithography and dry etch process;
depositing the antifuse dielectric layer on an uppermost surface of the plurality of second polymer layers and in the at least one via, the antifuse dielectric layer contacting the first redistribution layer at a bottom of the at least one via; and
forming the second redistribution layer on the plurality of second polymer layers, the second redistribution layer contacting the antifuse dielectric layer at least on a side of the at least one via and at the bottom of the at least one via.

14. The method of claim 13, further comprising:
removing a portion of the antifuse dielectric layer after deposition from the uppermost surface of the plurality of second polymer layers.

15. The method of claim 13, further comprising:
forming at least one of the first redistribution layer or the second redistribution layer using a semi-additive process (SAP).

16. The method of claim 13 comprising a fan-in or fan-out wafer-level packaging compatible process.

17. The method of claim 13, further comprising:
depositing an antifuse dielectric layer comprising a material based on at least one of amorphous silicon, silicon nitride, silicon oxide, silicon carbide, or metal oxide.

18. The method of claim 13, further comprising:
forming at least one of the first polymer layer or at least one of the plurality of second polymer layers from a material based on at least one of polybenzoxazole (PBO), polyimide, benzocyclobutene (BCB), epoxy, or photo-sensitive material.

19. The method of claim 13, further comprising:
etching a portion of the antifuse dielectric layer after deposition from the uppermost surface of the plurality of second polymer layers.

20. An apparatus for an embedded antifuse, comprising:
a first redistribution layer formed on a first polymer layer;
a plurality of second polymer layers formed on the first redistribution layer and the first polymer layer;
at least one via extending from a top surface of one of the plurality of second polymer layers to the first redistribution layer;
an antifuse dielectric layer formed in the at least one via and on the first redistribution layer at a bottom of the at least one via; and
a second redistribution layer formed at least on the antifuse dielectric layer in at least the at least one via.
